(19) United States
(12) Patent Application Publication
(10) Pub. No.: US 2013/0175670 A1
(43) Pub. Date: Jul. 11, 2013

(54) ZENER DIODE STRUCTURE AND MANUFACTURING METHOD THEREOF

(71) Applicant: FU-SIN CHEN, HSINCHU COUNTY (TW)

(72) Inventor: FU-SIN CHEN, HSINCHU COUNTY (TW)

(73) Assignee: LEXTAR ELECTRONICS CORP., HSINCHU (TW)

(21) Appl. No.: 13/543,742

(22) Filed: Jul. 6, 2012

(30) Foreign Application Priority Data
Jan. 9, 2012 (TW) 101100779

(51) Int. Cl. H01L 29/866; H01L 21/329

(52) U.S. Cl. 257/603; 438/380; 257/E29.335; 257/E21.356

(57) ABSTRACT

An exemplary embodiment illustrates a zener diode structure, wherein the zener diode structure includes a first-type semiconductor layer, a second-type semiconductor layer, a first electrode, a second electrode, and an insulation layer. The second-type semiconductor layer is disposed in a designated area in the first-type semiconductor layer. The first electrode is disposed on the bottom side of the first-type semiconductor layer. The second electrode is disposed above the first-type and the second-type semiconductor layers in corresponding to the central area of the second-type semiconductor layer. The insulation layer is disposed above the first-type and the second-type semiconductor layers surrounding the second electrode. The disclosed zener structure having the insulation layer can reduce the short circuit issue resulting from overflow of an adhesive material during the zener diode packaging process.

### BACKGROUND

1. Technical Field

The present disclosure relates to a semiconductor structure and the manufacturing method thereof, in particular, to a zener diode structure and the manufacturing method thereof.

2. Description of Related Art

Since the zener diodes when operates at the reverse breakdown voltage thereof can stably supply the reverse breakdown voltage, thereby possess voltage stabilizing capability. Currently, zener diodes have been widely used in applications of rectifiers, voltage regulating circuits or voltage protection circuit. Moreover, the zener diodes in practice can connect with other electric components on the circuit board via soldering or can be packaged with integrated circuit onto a chip or a printed circuit board via conductive paste.

Please refer to FIG. 1, which illustrates a diagram of a conventional zener diode structure 10. The structure of a zener diode currently on the market is as shown in FIG. 1 having a first-type semiconductor layer 103 (e.g., n-type semiconductor layer), a second-type semiconductor layer 105 (e.g., p-type semiconductor layer), a passivation layer 107, and the metal pads 101, 109. The metal pads 101, 109 are electrically isolated pads having opposite polarities e.g., anode and cathode. Furthermore, the second-type semiconductor layer 105 is disposed in a specific area of the first-type semiconductor layer 103. The first-type semiconductor layer 103 and the second-type semiconductor layer 105 further attach to the metal pad 109 through the deposited passivation layer 107. The metal pad 101 is disposed on the bottom side of the first-type semiconductor layer 103 while the metal pad 109 is disposed on the top of both the first-type and the second-type semiconductor layers 103, 105. Moreover, the metal pad 101 in practice is packaged in the circuit boards or the chips while the metal pad 109 are connect to other embedded electric components via wire bonding.

However, as illustrated in FIG. 1 when the described zener diode is packaged on the circuit board 113 via conductive paste 111, the conductive paste 111 in practice would be squeezed during the packaging process causes adhesive overflow and electrically connects pads 109 and 101 forming short circuit, consequently reduce manufacturing yield rate.

### SUMMARY

An exemplary embodiment of the present disclosure provides a zener diode structure, wherein the zener diode structure by having an insulation layer disposed around an electrode placed on the top side of the zener diode structure can effectively reduce the short circuit issue resulting from overflow of the adhesive material during the zener diode packaging process.

An exemplary embodiment of the present disclosure provides a zener diode structure having a first-type semiconductor layer, a second-type semiconductor layer, a first electrode, a second electrode, and an insulation layer. The second-type semiconductor layer is disposed in a designated area of the first-type semiconductor layer. The first electrode is disposed on a bottom side of the first-type semiconductor layer. The second electrode is disposed on the first-type semiconductor layer and the second-type semiconductor layer The second electrode is disposed in corresponding to the central area of the second-type semiconductor layer. The insulation layer is disposed on the first-type and the second-type semiconductor layers surrounding the second electrode.

According to one exemplary embodiment of the present disclosure, the first-type semiconductor layer may be an n-type semiconductor layer and the second-type semiconductor layer may be a p-type semiconductor.

According to one exemplary embodiment of the present disclosure, the first-type semiconductor layer may be a p-type semiconductor layer and the second-type semiconductor layer may be an n-type semiconductor.

According to one exemplary embodiment of the present disclosure, the first electrode is a cathode and the second electrode is an anode.

According to one exemplary embodiment of the present disclosure, the insulation layer comprises of metal oxides.

According to one exemplary embodiment of the present disclosure, the insulation layer comprises of insulation material.

An exemplary embodiment of the present disclosure provides an manufacturing method of a zener diodes structure, including the following steps: firstly, providing a first electrode; afterward, forming a first-type semiconductor layer on the first electrode; next, forming a second-type semiconductor layer in a designated area of the first-type semiconductor layer; subsequently, forming a second electrode on the first-type and second-type semiconductor layers; and lastly, forming an insulation layer surrounding the second electrode and completely covering the sidewall of the second electrode.

To sum up, the present disclosure illustrates a zener diodes structure having an insulation layer surrounding the sidewall of the second electrode (e.g., oxidizing the outer margin of the second electrode via oxidation process to form the insulation layer) so as to prevent the occurrence of the short circuit issue resulting from overflow of the adhesive material during the zener diode packaging process thereby increase the manufacturing yield rate.

In order to further understand the techniques, means and effects of the present disclosure, the following detailed descriptions and appended drawings are hereby referred, such that, through which, the purposes, features and aspects of the present disclosure can be thoroughly and concretely appreciated; however, the appended drawings are merely provided for reference and illustration, without any intention to be used for limiting the present disclosure.

### BRIEF DESCRIPTION OF THE DRAWINGS

The accompanying drawings are included to provide a further understanding of the present disclosure, and are incorporated in and constitute a part of this specification. The drawings illustrate exemplary embodiments of the present disclosure and, together with the description, serve to explain the principles of the present disclosure.

FIG. 1 is a diagram illustrating a conventional zener diode structure.

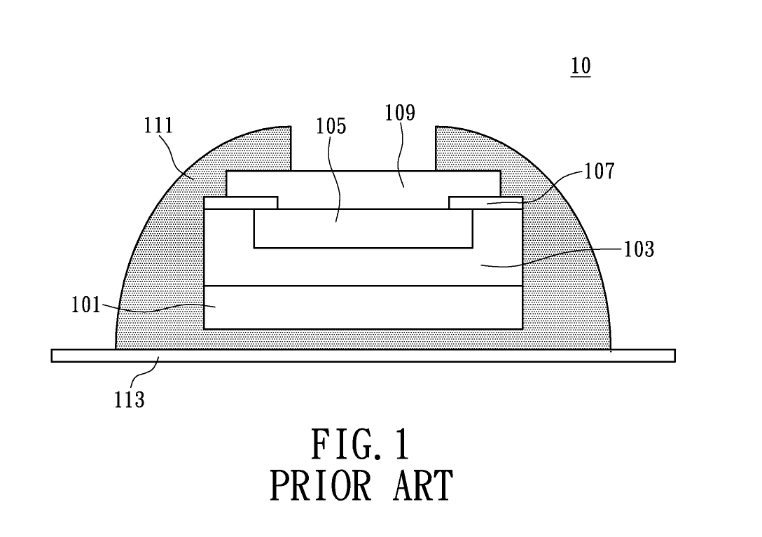

FIG. 2 is an exemplary diagram of a zener diode structure in accordance to the first exemplary embodiment of the present disclosure.

FIG. 3 is an exemplary diagram of a zener diode structure in accordance to the second exemplary embodiment of the present disclosure.

FIG. 4 is an exemplary diagram of a zener diode structure in accordance to the third exemplary embodiment of the present disclosure.

FIG. 5 is an exemplary flowchart illustrating a manufacturing method of a zener diode in accordance to the fourth exemplary embodiment of the present disclosure.

FIG. 6A˜6E are exemplary diagrams respectively illustrating the manufacturing method of the zener diode in accordance to the fourth exemplary embodiment of the present disclosure.

### DESCRIPTION OF THE EXEMPLARY EMBODIMENTS

Reference will now be made in detail to the exemplary embodiments of the present disclosure, examples of which are illustrated in the accompanying drawings. Wherever possible, the same reference numbers are used in the drawings and the description to refer to the same or like parts.

### First Exemplary Embodiment

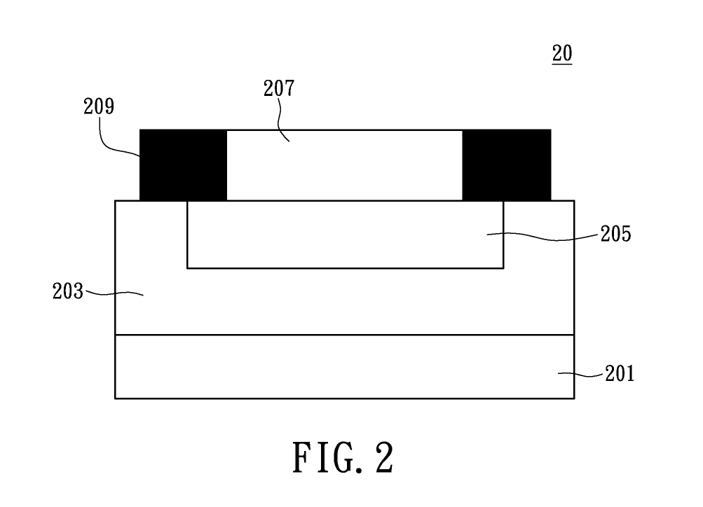

Please refer to FIG. 2, which illustrates an exemplary diagram of a zener diode structure in accordance to the first exemplary embodiment of the present disclosure. The zener diode structure 20 includes a first electrode 201, a first-type semiconductor layer 203, a second-type semiconductor layer 205, a second electrode 207 and an insulation layer 209.

The first-type semiconductor layer 203 is a semiconductor layer doped with a first-type dopant, wherein the first-type dopant may be an n-type dopant. The second-type semiconductor layer 205 is a semiconductor layer doped with a second-type dopant, wherein the second-type dopant may be a p-type dopant. However, in practice the first-type dopant may be a p-type dopant and the second-type dopant may be an n-type dopant, hence the instant embodiment does not limit the actual type of the first-type and the second-type dopants. The first electrode 201 and the second electrode 207 are metal electrode of opposite polarities. In the instant embodiment, the first electrode 201 is configured as an anode and the second electrode 207 is configured as a cathode, however the instant embodiment is not limited thereto. The insulation layer 209 may be for example comprises of metal oxides or insulation material e.g., silicon dioxide or silicon nitride, however the instant embodiment is not limited to the example provided herein.

It is worth to note, the first electrode 201 and the second electrode 207 may each for example comprises of metallic material. However, in practice the first electrode 201 and the second electrode 207 may also comprises of other conductive material such as silicon, graphite, or boron. Thus, the instant embodiment does not limit the actual implementation of the first electrode 201 and the second electrode 207. Moreover, taking the first-type semiconductor layer 203 as an n-type semiconductor layer for instance, can be implemented by phosphorus doped silicon, arsenic doped silicon, or antimony ion doped silicon; taking the second-type semiconductor layer 205 as a p-type semiconductor layer for instance, can be implemented by boron ion doped silicon, however the instant embodiment is not limited thereto. The method for doping trivalence or pentavalent ions may for example be ion implantation, however the instant embodiment is not limited by the examples provided herein

Furthermore, the first electrode 201 is disposed on the bottom side of the first-type semiconductor layer 203 and is electrically connected to the first-type semiconductor layer 203. The first electrode 201 covers the bottom side of the first-type semiconductor layer 203. The second-type semiconductor layer 205 is disposed in a designate area of the first-type semiconductor layer 203. The second-type semiconductor layer 205 may be formed by doping the second-type dopant in the designate area of the first-type semiconductor layer 203. The formed second-type semiconductor layer 205 has a flat surface and a height equal to the height of the upper surface of the first-type semiconductor layer 203. The second electrode 207 can be grew on the top of both the first-type semiconductor layer 203 and the second-type semiconductor layer 205 via metal thin film deposition and sputtering deposition to electrically connected with the second-type semiconductor layer 205. To put it concretely, the second electrode 207 is disposed in the central area of the second-type semiconductor 205 and is electrically isolated from the first-type semiconductor layer 203.

The zener diode structure 20 further has the insulation layer 209 disposed on the first-type semiconductor layer 203 and the second-type semiconductor layer 205 surrounding the second electrode 207. Specifically, the insulation layer 209 may comprise of insulation material and partially overlaps the first-type semiconductor layer 203 and the second-type semiconductor layer 205, respectively. The insulation layer 209 extends over to the sidewall of the second electrode 207 while electrically isolated from the first electrode 201, the first-type semiconductor layer 203, the second-type semiconductor layer 205, and the second electrode 207, respectively. Moreover, the height of the insulation layer 209 may surround and cover the sidewall of the second electrode 207. As shown in FIG. 2, the height of the insulation layer 209 may be equal to the height of the second electrode 207. In other embodiments, the height of the insulation layer 209 may be greater than or lower than the height of the second electrode 207. The insulation layer 209 in the instant embodiment comprises of metallic material, consequently the insulation layer may be formed by oxidizing the outer margin of the second electrode 207.

Accordingly, the disclosed zener diode structure 20 through placing the insulation layer 207 surrounding the second electrode 207 may effectively prevent the possibility of having the second electrode 207 electrically connected to the silver paste or conductive paste. Thus, prevents the first electrode 201 electrically connecting to the second electrode 207 from overflowing of the adhesive material and result in short circuit.

### Second Exemplary Embodiment

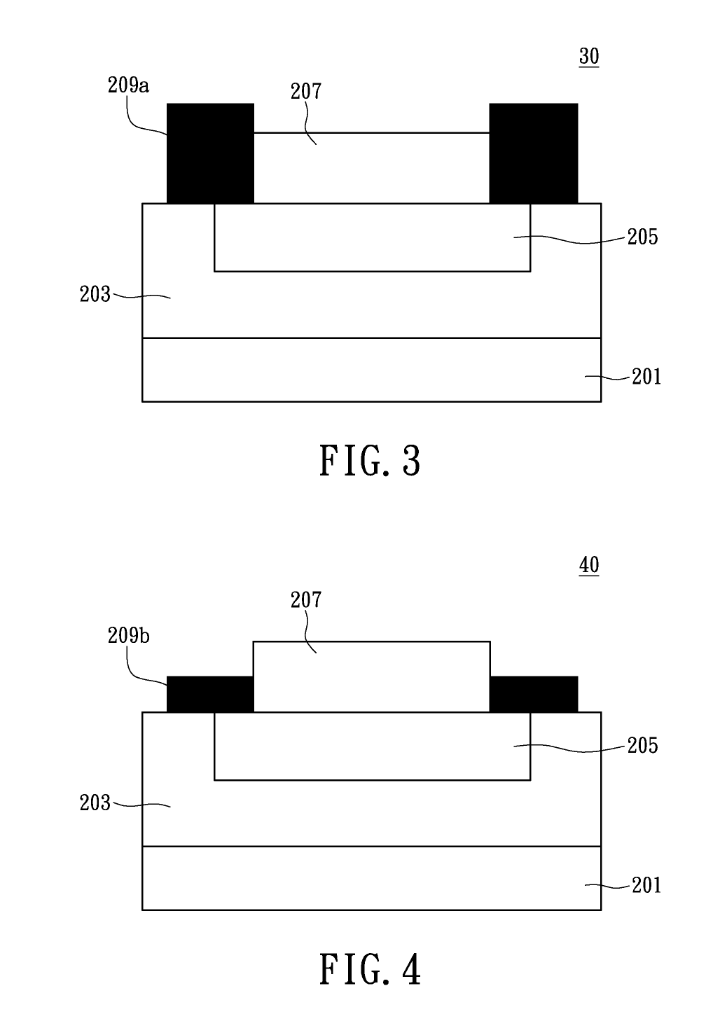

The aforementioned insulation layer 209 may be taken on different form. Please refer to FIG. 3 which illustrates a zener diode structure in accordance to the second exemplary embodiment of the present disclosure. The difference between the zener diode structure 20 of FIG. 2 and the zener diode structure 30 of FIG. 3 is that the height associated with the insulation layer 209a of the zener diode structure 30 is higher than the height of the second electrode 207.

In particular, the insulation layer 209a of the instant embodiment may be formed using insulation material such as silicon nitride or silicon dioxide and covering the top surface of the first-type semiconductor layer 203 and the second-type semiconductor layer 205. The insulation layer 209a is electrically isolated from the first-type semiconductor layer 203 and the second-type semiconductor layer 205. The second electrode 207 may therefore electrically connected to the second-type semiconductor layer 205 while electrically isolated from the first-type semiconductor layer 203.

Furthermore, the rest structure of the zener diode structure 30 is essentially the same as the zener diode structure 20 of FIG. 2, hence based on the above explanations, those skilled in the art should be able to infer the actual structure and implementation method associated with the zener diode structure 30, further descriptions are therefore omitted.

It is worth to note that the height of the insulation layer 209 in the instant embodiment is higher than the height of the second electrode 207. However, the actual height of the insulation layer 209a may be implemented according to actual design needs, thus shall not be limited by the instant embodiment. Moreover, the structure of the insulation layer 209a in the instant embodiment is a more preferable implementation in comparison to the insulation layer 209 of the first embodiment as the height of the insulation layer 209a being higher than the height of the second electrode 207. Hence the structure may effectively prevent the silver paste or conductive paste crossing over the insulation layer 209a and electrically connect the second electrode 207 which causes the first electrode 201 electrically connecting to the second electrode 207 forming short circuit during the packaging process.

### Third Exemplary Embodiment

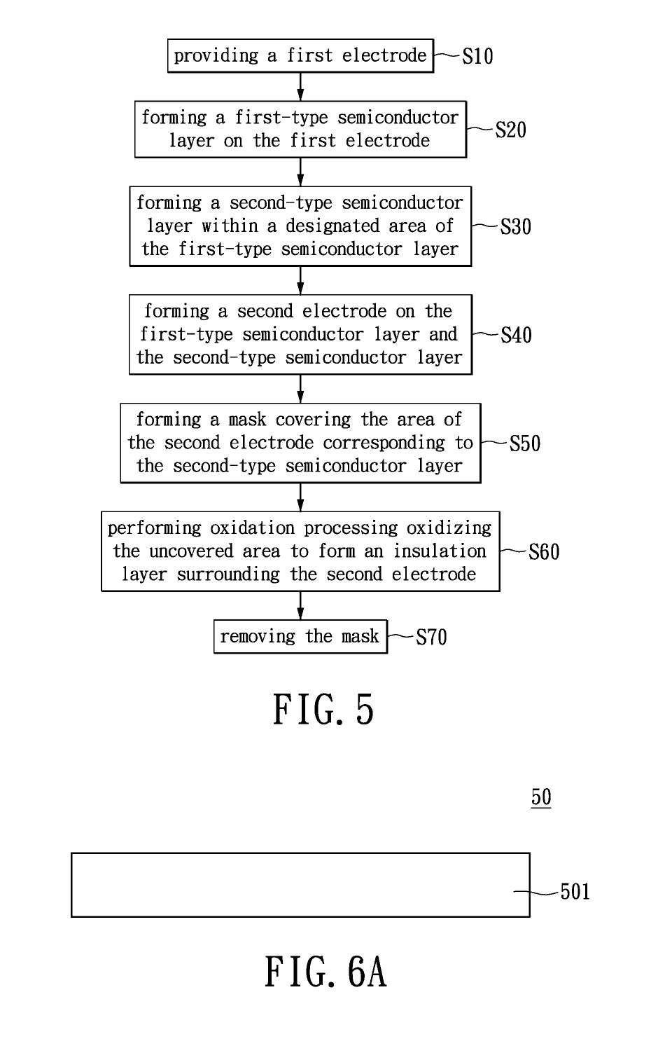

The aforementioned insulation layer 209 may further take on other form. Please refer to FIG. 4, which illustrates an exemplary diagram of a zener diode structure in accordance to the third exemplary embodiment of the present disclosure. The difference between the zener diode structure 40 of FIG. 4 and the zener diode structure 20 is in that the insulation layer 209b of the zener diode structure 40 is disposed above the first-type semiconductor layer 203 and the second-type semiconductor layer 205 but with the insulation layer 209b having the height lower than the height of the second electrode 207, e.g., half of the height of the second electrode 207. However, the instant embodiment does not limit the actual height of the insulation layer 209b.

The rest structure of the zener diode structure 40 is essentially the same as the zener diode structure 20 of FIG. 2, thus based on the above explanations, those skilled in the art should be able to deduce the actual structure and implementation method associated with the zener structure 40, further descriptions are therefore omitted.

### Fourth Exemplary Embodiment

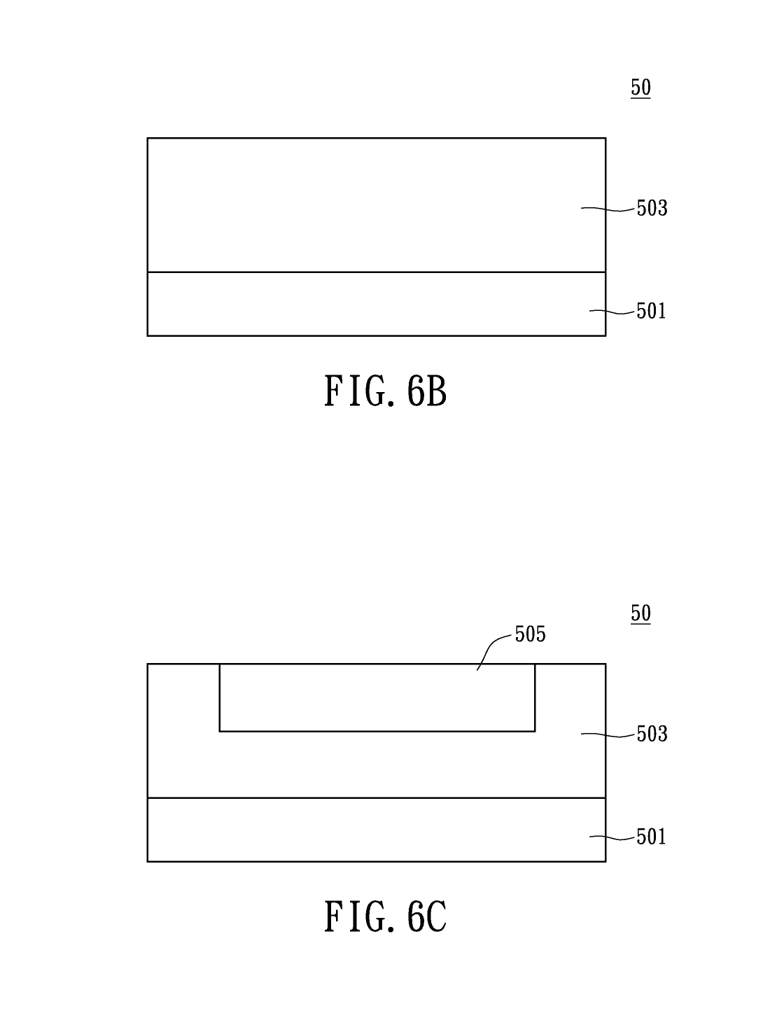

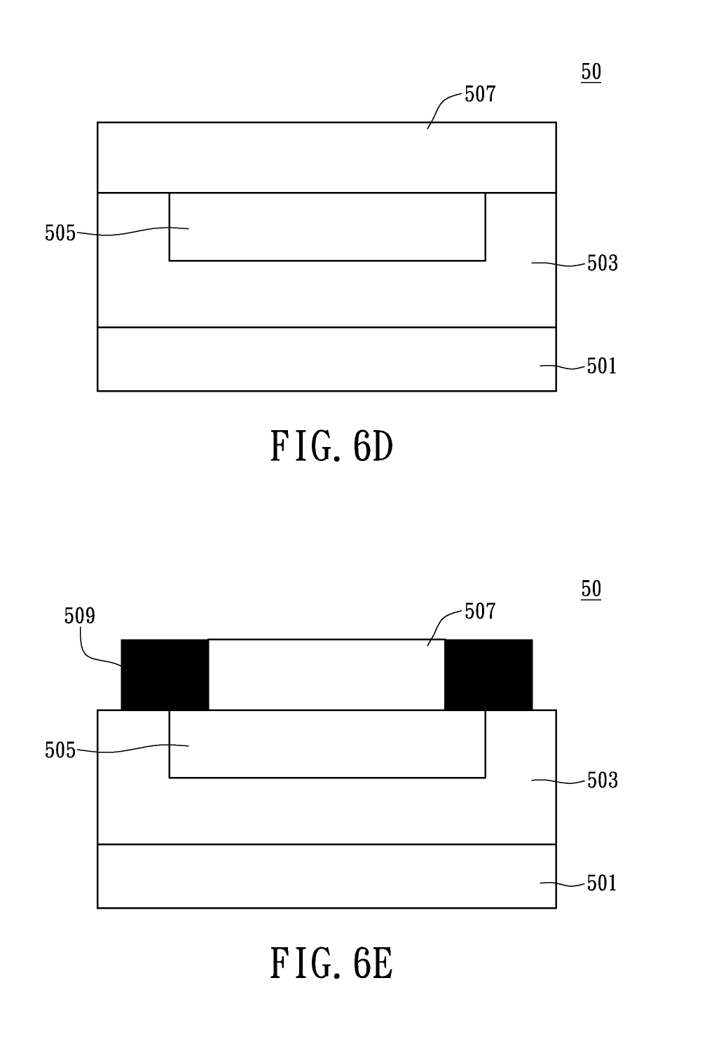

Next, please refer to FIG. 5 in conjunction with FIG. 6A˜FIG. 6E.

FIG. 5 shows an exemplary flowchart illustrating a manufacturing method of a zener diode in accordance to the fourth exemplary embodiment of the present disclosure. FIG. 6A˜6E respectively show exemplary diagrams for illustrating the manufacturing method of the zener diode in accordance to the fourth exemplary embodiment of the present disclosure.

In Step S10 (as shown in FIG. 6A), provides a first electrode 501, wherein the first electrode 501 may comprise of a metallic material and is configured as a cathode.

Afterward, as shown in FIG. 6B, forms a first-type semiconductor layer 503 having a first-type dopant on top of the first electrode 501 (Step S20). The first-type dopant of the instant embodiment can be an n-type dopant and may comprise of phosphorus doped silicon, arsenic doped silicon, or antimony ion doped silicon, however, the instant embodiment is not limited to the examples provided herein.

Subsequently, as shown in FIG. 6C, forms a second-type semiconductor layer 505 by implanting a second-type dopant into a designate area of the first-type semiconductor layer 503(Step S30). The second-type dopant of the instant embodiment may be a p-type dopant and may comprise of boron ion doped silicon however, the instant embodiment is not limited thereto.

Incidentally, in practice the first-type dopant may be a p-type dopant and the second-type dopant may be an n-type dopant. Hence, the instant embodiment does not limit the actual type of the first-type dopant and the second-type dopant. In addition, the first-type semiconductor layer 503 and the second-type semiconductor layer 505 may be implemented by using chemical vapor deposition (CVD) method.

Next, in Step S40 and as shown in FIG. 6D, form a second electrode 507 with a predefined height covering the first-type semiconductor layer 503 and the second-type semiconductor layer 505 via methods of metal thin film deposition and sputtering deposition. The second electrode 507 of the instant embodiment may be formed using metallic material and configured as an anode.

Afterward in Step S50, develop a mask (not shown) via exposure and developing process covering the central area of the second electrode 507 which corresponds to the second-type semiconductor layer 505 so as to respectively form a covered region (i.e., conductive region) and an exposure region. Next, performs an oxidation process and a thermal process to the exposure region of the second electrode 507 to oxidize the region uncovered by the mask (i.e. the exposure region) thereby forming an oxidation layer or an insulation layer 509 surrounding the covered region and electrically isolated from the second electrode 507 (Step S60).

Additionally, the insulation layer 509 partially overlaps the first-type semiconductor layer 503 and the second-type semiconductor layer 505, respectively. The oxidation process may be for example implemented using oxidation method including but not limited to thermal oxidation, weak alkaline oxidation, or weak acid oxidation in accordance to the actual manufacturing requirements.

Then in Step S70, removes the mask via etching or stripping process to shape the second electrode 507 and the insulation layer 507 as shown FIG. 6E thereby forming the zener diode structure 50.

Incidentally, the mask may be implemented using material like silicon dioxide. In addition, as previously described the mask can be patterned using photolithography technique so as to have the covered region covering the surface of the second electrode 507 with a specific shape. The described shape may according to the actual design requirements be a square, a rectangular, an ellipse, a diamond, a polygon or any other types of geometrical shape, and the instant embodiment is not limited thereto.

It is worth to note that in the manufacturing method of the zener diode structure 50 of FIG. 5, the insulation layer 509 comprises of metal oxide and has the same height as the second electrode 507. However, the required height ratio between the second electrode 507 and the insulation layer 509 may be formed according to the manufacturing needs through processes of mask covering, etching and stripping. In one implementation, the insulation layer 509 can be covered using mask and thereafter through etching process reduce the height of the second electrode 507 to have the height of the insulation layer 509 greater than the height of the second electrode 507. In another implementation, the second electrode 507 can be covered using mask and reduce the height of the insulation layer 207 via etching process to have the height of the insulation layer 509 lower than the height of the second electrode 507.

The insulation layer 509 as described in the aforementioned embodiment may be implemented using insulation material. Specifically, after Step S30, the silicon dioxide or silicon nitride insulation layer 509 may be formed on the first-type and the second-type semiconductor layers. Subsequently, through etching process, remove the central area in correspondence to the second-type semiconductor layer 509 of the insulation layer 509. Then deposits the second electrode 507 in the removed area electrically connecting the second-type semiconductor layer 509 via method of metal thin film deposition and sputtering deposition. In addition, the required height ratio between the insulation layer 509 and the second electrode 507 may be formed using the chemical vapor deposition method. Based on the above-described explanations, those skilled in the art should be able to deduce the implantation method of the insulation layer 509 as well as forming the required height ratio between the insulation layer 509 and the second electrode 507, and further descriptions are therefore omitted. It shall be noted that FIG. 6A˜6E only serve to illustrate the manufacturing process of the zener diode in accordance to the fourth exemplary embodiment. Hence the present disclosure is not limited thereto.

In summary, the zener diode structure provided by the exemplary embodiment of the present disclosure deposits an insulation layer surrounding the sidewall of the second electrode in the disclosed zener diode structure, wherein the height ratio between the insulation layer and the second electrode may be configured according to the manufacturing needs. The manufacturing method for forming the insulation layer may be for example by oxidized the outer margin of the second electrode via oxidation process. The disclosed zener diode structure may therefore effectively reduce or even prevent the occurrence of the short circuit issue resulting from overflow of the silver paste or the conductive pester during the zener diode packaging process thereby increase the manufacturing yield rate.

The above-mentioned descriptions represent merely the exemplary embodiment of the present disclosure, without any intention to limit the scope of the present disclosure thereto. Various equivalent changes, alternations or modifications based on the claims of present disclosure are all consequently viewed as being embraced by the scope of the present disclosure.

What is claimed is:

1. A zener diode structure, comprising:
a first-type semiconductor layer;
a second-type semiconductor layer, disposed in a designated area of the first-type semiconductor layer;
a first electrode, disposed on a bottom side of the first-type semiconductor layer;
a second electrode, disposed on the first-type and the second-type semiconductor layers; and
an insulation layer, disposed on the first-type and the second-type semiconductor layers, surrounding the second electrode.

2. The zener diode structure according to claim 1, wherein the first-type is an n-type and the second-type is a p-type.

3. The zener diode structure according to claim 2, wherein the first electrode is a cathode and the second electrode is an anode.

4. The zener diode structure according to claim 1, wherein the first-type is a p-type and the second-type is an n-type.

5. The zener diode structure according to claim 4, wherein the first electrode is an anode and the second electrode is a cathode.

6. The zener diode structure as in any of claims 1, wherein the height of the insulation layer is greater than or equal to the height of the second electrode.

7. The zener diode structure as in any of claims 1, wherein the insulation layer is formed by having the outer margin of the second electrode oxidized.

8. The zener diode structure according to claim 7, wherein the second electrode comprises of metallic material.

9. The zener diode structure according to claim 8, wherein the insulation layer comprises of metal oxides.

10. The zener diode structure according to claim 1, wherein the insulation layer comprises of insulation material.

11. The zener diode structure according to claim 1, wherein the insulation material partially overlaps the first-type semiconductor layer and the second-type semiconductor layer, respectively.

12. A manufacturing method of a zener diode structure, comprising:
providing a first electrode;
forming a first-type semiconductor layer on the first electrode;
forming a second-type semiconductor layer in a designated area of the first-type semiconductor layer;
forming a second electrode on the first-type and the second-type semiconductor layers; and
forming an insulation layer surrounding the second electrode and completely covering the sidewall of the second electrode.

13. The manufacturing method according to claim 12, wherein the first-type is an n-type and the second-type is a p-type.

14. The manufacturing method according to claim 13, wherein the first electrode is a cathode and the second electrode is an anode.

15. The manufacturing method according to claim 12, wherein the first-type is a p-type and the second-type is an n-type.

16. The manufacturing method according to claim 15, wherein the first electrode is an anode and the second electrode is a cathode.

17. The manufacturing method as in any of claims 12, wherein the height of the insulation layer is greater than or equal to the height of the second electrode.

18. The manufacturing method as in any of claims 12, wherein the second electrode comprises of metallic material.

19. The manufacturing method according to claim 18, wherein the step of forming the insulation layer further comprises of:
providing a mask covering a central area of the second electrode corresponding to the second-type semiconductor layer;
performing an oxidation process to oxidize the area of the second electrode uncovered by the mask to form a metal oxide insulation layer; and
removing the mask.

20. The manufacturing method according to claim 18, wherein the step of forming the second-type semiconductor layer further comprises of:
doping a second-type dopant into the designated area of the first-type semiconductor layer to form the second-type semiconductor layer.
